(19) United States
(12) Patent Application Publication
(10) Pub. No.: US 2023/0266370 A1
(43) Pub. Date: Aug. 24, 2023

(54) METHOD, APPARATUS AND SYSTEM FOR MEASURING NONLINEAR RELATED PARAMETERS OF NONLINEAR DEVICE

(71) Applicant: FUJITSU LIMITED, Kawasaki-shi (JP)

(72) Inventors: Tong YE, Beijing (CN); Zhenning TAO, Beijing (CN)

(73) Assignee: FUJITSU LIMITED, Kawasaki-shi (JP)

(21) Appl. No.: 18/138,368

(22) Filed: Apr. 24, 2023

Related U.S. Application Data
(63) Continuation of application No. PCT/CN2020/125268, filed on Oct. 30, 2020.

(51) Int. Cl. G01R 23/20; G01R 23/165; H04B 17/10

(52) U.S. Cl. CPC G01R 23/20; G01R 23/165; H04B 17/104

(57) ABSTRACT

A method, an apparatus and a system to measure nonlinear related parameters of a nonlinear device. The apparatus comprises a memory and a processor coupled to the memory to control execution of a process to: generate a first signal according to a signal to be measured, the first signal and the signal to be measured having a signal probability distribution that is same, and the first signal having at least one notch frequency; and calculate, according to an output signal of the nonlinear device when the first signal is input into the nonlinear device, nonlinear related parameters of the nonlinear device when the signal to be measured is transmitted.

### CROSS-REFERENCE TO RELATED APPLICATIONS

This application is a continuation application of PCT International Application No. PCT/CN2020/125268, filed Oct. 30, 2020, in the China National Intellectual Property Administration, the disclosure of which is incorporated herein by reference.

### TECHNICAL FIELD

The present application relates to the field of communication technology.

### BACKGROUND

In the field of radio frequency microwaves, communications, and optical communications, in order to achieve signal transmission at greater bandwidth and more frequency bands, more and more high frequency devices such as 40 GHz bandwidth radio frequency amplifiers, broadband coherent optical receivers (with transimpedance amplifiers) are put into application. However, high frequency devices tend to have some performance imperfections. For example, broadband radio frequency amplifiers may have nonlinear effects that degrade the signal transmission performance of high frequency devices. Therefore, the researchers put forward some indexes and measurement methods to measure the magnitude of the nonlinear effects in the devices, which may be used to optimize the design of devices, predict the effects of nonlinear degradation and select the correct devices and the like.

The most commonly used index for measuring non-linear effects is total harmonic distortion (THD), i.e., the degree of non-linearity is estimated by observing the magnitude of the harmonic wave generated by an input signal of a single frequency at an output end of the system under test. However, this method is very inaccurate, especially in larger bandwidth applications, where the nonlinear magnitudes at high and low frequencies are far apart.

Another existing method is to pass the signal to be measured through band-stop filtering to form a signal with notches (i.e. a notch signal). The notch signal passes through the nonlinear device to obtain an output signal, the power at the notch position in the output signal is measured as nonlinear noise. The nonlinear noise reflects the nonlinear degree of the nonlinear device when transmitting the signal to be measured. This method is called a conventional power to noise ratio (PNR) test method.

The aforementioned THD or PNR may be referred to as nonlinear related parameters of the nonlinear device.

FIG. 1 is a schematic diagram of a conventional PNR test method. As shown in FIG. 1, the signal to be measured 100 is subjected to a band-stop filtering 101 to form a notch signal 102, the notch signal 102 is input into a nonlinear device 103, an output signal of the nonlinear device 103 is 104, and in a calculation step 105, a PNR of the output signal 104 is calculated as a nonlinear related parameter of the nonlinear device 103 when transmitting the signal to be measured 100.

It should be noted that, the above introduction to the background is merely for the convenience of clear and complete description of the technical solution of the present application, and for the convenience of understanding of persons skilled in the art. It cannot be regarded that the above technical solution is commonly known to persons skilled in the art just because that the solution has been set forth in the background of the present application.

### SUMMARY

Embodiments of the present application provide a method for measuring nonlinear related parameters of a nonlinear device, an apparatus and a system for the same, which generate a notch signal having the same signal probability distribution as the signal to be measured, and based on the notch signal, calculates nonlinear related parameters (such as nonlinear noise power) of the nonlinear device when the signal to be measured is transmitted, thus, the nonlinear related parameters may be accurately calculated for the signal to be measured having any signal probability distribution, and furthermore, the use of expensive high-frequency waveform analysis equipment may be avoided.

According to a first aspect of an embodiment of the present application, there is provided with an apparatus for measuring nonlinear related parameters of a nonlinear device, including:
a first signal generating unit configured to generate a first signal according to a signal to be measured, the first signal and the signal to be measured having the same signal probability distribution, and the first signal having at least one notch frequency; and
a processing unit configured to, according to an output signal of the nonlinear device when the first signal is inputted into the nonlinear device, calculate nonlinear related parameters of the nonlinear device when the signal to be measured is transmitted by the nonlinear device.

According to a second aspect of an embodiment of the present application, there is provided with a method for measuring nonlinear related parameters of a nonlinear device, including:
generating a first signal according to a signal to be measured, the first signal and the signal to be measured having the same signal probability distribution, and the first signal having at least one notch frequency; and
according to an output signal of the nonlinear device when the first signal is inputted into the nonlinear device, calculating nonlinear related parameters of the nonlinear device when the signal to be measured is transmitted by the nonlinear device.

According to a third aspect of an embodiment of the present application, there is provided with a system for measuring filtering characteristics, wherein the system includes an apparatus for measuring nonlinear related parameters of a nonlinear device according to the first aspect mentioned above and a nonlinear device.

One of the advantageous effects of the embodiments of the present application is that, a notch signal having the same signal probability distribution as the signal to be measured is generated, and based on the notch signal, nonlinear related parameters of the nonlinear device when the signal to be measured is transmitted are calculated, thus, the nonlinear related parameters may be accurately calculated for the signal to be measured having any signal probability distribution, and furthermore, the use of expensive high-frequency waveform analysis equipment may be avoided.

With reference to the Description and drawings below, a specific embodiment of the present application is disclosed in detail, which specifies the manner in which the principle of the present application may be adopted. It should be understood that, the scope of the embodiment of the present application is not limited. Within the scope of the spirit and clause of the appended claims, the embodiment of the present application includes many variations, modifications and equivalents.

The features described and/or shown for one embodiment can be used in one or more other embodiments in the same or similar manner, can be combined with the features in other embodiments or replace the features in other embodiments.

It should be emphasized that, the term “include/contain/comprise” refers to, when being used in the text, existence of features, parts, steps or assemblies, without exclusion of existence or attachment of one or more other features, parts, steps or assemblies.

### BRIEF DESCRIPTION OF DRAWINGS

Many aspects of the present application may be better understood with reference to the following drawings. The components in the drawings are not drawn to scale, but merely to illustrate the principle of the present application. For ease of illustration and description of some portions of the present application, corresponding portions of the drawings may be enlarged or reduced. Elements and features described in one drawing or one embodiment of the present application may be combined with elements and features illustrated in one or more other drawings or embodiments. Furthermore, in the drawings, like reference numerals refer to corresponding parts in the several drawings and may be used to indicate corresponding parts used in more than one embodiment.

In the drawings:

FIG. 1 is a schematic diagram of a conventional PNR test method;

FIG. 2 is a flowchart of a method for measuring nonlinear related parameters of a nonlinear device according to an embodiment of the present application;

FIG. 3 is a schematic diagram of an example of the method shown in FIG. 2 according to an embodiment of the present disclosure;

FIG. 4 is a schematic diagram of a method of generating a first signal according to an embodiment of the present disclosure;

FIG. 5 is a schematic diagram of operation 401 according to an embodiment of the present disclosure;

FIG. 6 is a schematic diagram of one embodiment of operation 402 according to the present disclosure;

FIG. 7 is a schematic diagram of another embodiment of operation 402 according to the present disclosure;

FIG. 8 is a schematic diagram of the signal probability distribution of the current notch signal and the signal to be measured according to an embodiment of the present disclosure;

FIG. 9 is another schematic diagram of a method of generating a first signal according to an embodiment of the present disclosure;

FIG. 10 is a schematic diagram of the effect of the method for measuring nonlinear related parameters of a nonlinear device according to an embodiment of the present application;

FIG. 11 is a schematic diagram of an apparatus for measuring nonlinear related parameters of a nonlinear device according to an embodiment of the present application;

FIG. 12 is a schematic diagram of one embodiment of a first signal generating unit according to the present disclosure;

FIG. 13 is a schematic diagram of another embodiment of a first signal generating unit according to the present disclosure;

FIG. 14 is a schematic diagram showing the configuration of a system for measuring nonlinear related parameters of a nonlinear device according to embodiments of the present application; and

FIG. 15 is a configuration diagram of an electronic device according to an embodiment of the present application.

### DESCRIPTION OF EMBODIMENTS

With reference to the drawings, the foregoing and other features of the embodiments of the present application will become apparent through the following description. These embodiments are exemplary only and are not limiting of the present application. To enable those skilled in the art to readily understand the principles and embodiments of the present application, the embodiments of the present application will be described using a reconstructed image of image compression process as an example. However, it is understood that the embodiments of the present application are not limited thereto, and the reconstructed images based on other image processing are also within the scope of the present application.

In embodiments of the present application, the terms “first,” “second,” and the like are used to distinguish different elements from each other in terms of appellation, but do not denote the spatial arrangement or temporal order or the like of these elements, and these elements should not be limited by these terms. The term “and/or” includes any one and all combinations of one or at least two of the associated listed terms. The terms “containing”, “including”, “having” and the like refer to presence of the stated features, elements, components or assemblies, but do not exclude presence or addition of one or at least two other features, elements, components or assemblies.

In embodiments of the present application, the singular form “a” “the” and the like includes the plural form, and is to be understood in a broad sense as “a kind” or “a type” and is not limited to “one”; in addition, the term “said” is to be understood to include both singular and plural forms, unless otherwise specified clearly in the context. In addition, the term “according to” shall be understood to mean “at least partially according to ...” and the term “based on” shall be understood to mean “based at least partially on ...”, unless otherwise specified clearly in the context.

The inventor of the present application found that sometimes the measured nonlinear noise is inaccurate when the conventional PNR test method is used. The inventor has further investigated that the magnitude of the nonlinear noise is related to the signal probability distribution function (PDF). After the signal to be measured is subjected to band-stop filtering, the signal probability distribution of the formed notch signal varies with respect to the signal probability distribution of the signal to be measured. Therefore, the nonlinear noise calculated based on the notch signal varies with respect to the nonlinear noise practically generated when the signal to be measured passes through the nonlinear device. In particular, for the signal to be measured with non-Gaussian distribution, after it is subjected to band-stop filtering, the signal probability distribution of the formed notch signal varies more than the signal probability distribution of the signal to be measured, and therefore, the deviation of the calculated nonlinear noise is also larger. For a real signal, the signal probability distribution refers to the probability distribution of the amplitude of the real signal, and for a complex signal, the signal probability distribution refers to the probability distribution of the modulus of the complex signal.

Specific embodiments of the present application are described below with reference to the drawings.

### Embodiment 1

Embodiment 1 of the present application provides a method for measuring nonlinear related parameters of a nonlinear device, and FIG. 2 is a flowchart of the method. As shown in FIG. 2, the method includes:
201, a first signal is generated according to a signal to be measured, the first signal and the signal to be measured having the same signal probability distribution, and the first signal having at least one notch frequency; and
202, according to an output signal of the nonlinear device when the first signal is inputted into the nonlinear device, nonlinear related parameters of the nonlinear device when the signal to be measured is transmitted is calculated.

Since the magnitude of nonlinear noise is associated with the signal probability distribution function (PDF), in Embodiment 1, the first signal having a notch frequency and the signal to be measured have the same signal probability distribution. Therefore, the nonlinear noise calculated based on the first signal may accurately reflect the nonlinear noise practically generated when the signal to be measured passes through the nonlinear device. That is, the method according to Embodiment 1 may accurately calculate the nonlinear related parameters of the nonlinear device when the nonlinear device transmits the signal to be measured.

In the present embodiment, the nonlinear related parameters are parameters capable of measuring a nonlinear effect of the nonlinear device, and the nonlinear related parameters may be, for example, a power to noise ratio (PNR) of an output signal of the nonlinear device. In addition, the present embodiment may not be limited to this, and the nonlinear related parameters may also be other parameters calculated based on the output signal of the nonlinear device.

In the present embodiment, for a real signal, the signal probability distribution refers to the probability distribution of an amplitude of the real signal in the time domain, and for a complex signal, the signal probability distribution refers to the probability distribution of a modulus of the complex signal in the time domain.

The signal to be measured changes (for example, the frequency, power and/or signal probability distribution, etc. of the signal to be measured change), and the nonlinear related parameters of the nonlinear device when the nonlinear device transmits the signal to be measured also usually change. Therefore, through the method of Embodiment 1, the nonlinear related parameters of the nonlinear device when different signals to be measured are transmitted by the nonlinear device may be measured accurately, so as to form a corresponding relationship among the signal to be measured, the nonlinear device and the nonlinear related parameters, and the corresponding relationship may be used to optimize the design of the nonlinear device, predict the effects of nonlinear degradation and select correctly the nonlinear device and the like.

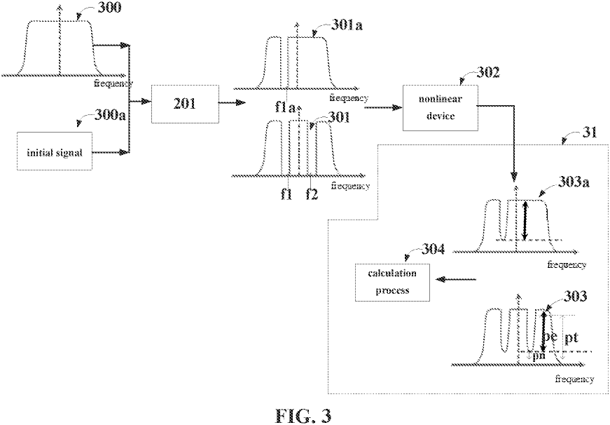

FIG. 3 is a schematic diagram of an example of the method shown in FIG. 2. As shown in FIG. 3, in the method for measuring nonlinear related parameters of a nonlinear device, operation 201 of FIG. 2 forms a first signal 301 according to a signal to be measured 300 and an initial signal 300a, the first signal 301 is input to a nonlinear device 302, an output signal of the nonlinear device 302 is 303, the PNR of the output signal 303 is calculated in the calculation process 304, and the calculated PNR is served as a nonlinear related parameter of the nonlinear device 302 when the nonlinear device 302 transmits the signal to be measured 300.

The dashed box 31 in FIG. 3 represents a step corresponding to operation 202 of FIG. 2. In the calculation process 304, the signal power pn at the notch frequency of the output signal 303 may be taken as the power of the nonlinear noise, and the signal power pt at frequencies other than the notch frequency of the output signal 303 may be taken as the sum of the power of the nonlinear noise and the effective signal power pe, whereby pe = pt - pn, PNR = (pt - pn) / pn, and PNR may be taken as the nonlinear related parameter. In addition, in the calculation process 304, the nonlinear related parameter may also be calculated by using other methods.

As shown in FIG. 3, the first signal 301 may have two sets of notch frequencies f1 and f2, and f1 and f2 are symmetric. In addition, in other examples, f1 and f2 may also be asymmetric. Alternatively, the first signal has only one notch frequency f1a (for example, shown as first signal 301a in FIG. 3), or the first signal has three or more notch frequencies. In addition, the more than one notch frequency of the first signal may be distributed symmetrically or asymmetrically. Here, as shown in FIG. 3, in the case where the first signal is 301a, the output signal of the nonlinear device 302 is 303a.

In this embodiment, the signal to be measured 300 and the first signal 301 (301a) may both be real signals, or the signal to be measured 300 and the first signal 301 (301a) may both be complex signals.

In this embodiment, total power of the first signal is to the same with total power of other frequency parts in the signal to be measured than the notch frequency, here, “the same” means that the absolute value of a difference therebetween is not greater than a predetermined threshold value T1, which may be, for example, 0.05%. For example, when the total power of the first signal 302 shown in FIG. 3 is p1 (not shown) and the total power of other frequency portions of the signal to be measured 300 other than f1 and f2 is p2 (not shown), |p1-p2| ≤ T1, whereby the influence of the variation of the signal power on the nonlinear correlation parameter may be eliminated.

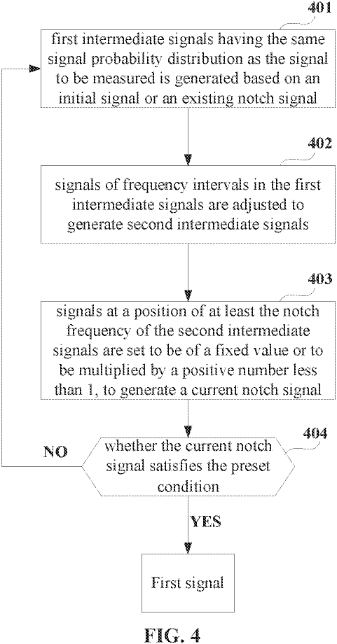

FIG. 4 is a schematic diagram of a method of generating a first signal, for implementing operation 201 of FIG. 2. The method includes:
401, first intermediate signals having the same signal probability distribution as the signal to be measured is generated based on an initial signal or an existing notch signal;
402, signals of frequency intervals in the first intermediate signals is adjusted, to generate second intermediate signals, power of signals in frequency intervals in the second intermediate signals being identical to power of signals in corresponding frequency intervals in the signal to be measured; and
403, signals at a position of at least the notch frequency of the second intermediate signals are set to be of a fixed value or to be multiplied by a positive number less than 1, to generate a current notch signal.

As shown in FIG. 4, the method of generating a first signal may further include:

404, it is determined whether the current notch signal satisfies the preset condition.

When it is determined in the operation 404 that the current notch signal generated in the operation 403 satisfies the preset condition, the current notch signal is taken as the first signal, and the operation 201 is completed. In addition, when it is determined in the operation 404 that the current notch signal generated in the operation 403 does not satisfy the preset condition, the current notch signal is served as the existing notch signal in the operation 401, and the processing of operations 401, 402 and 403 is performed again.

In this embodiment, the operation 401 may change the spectrum (i.e., power) of the initial signal or the existing notch signal. The operation 402 changes the signal probability distribution of the first intermediate signals and the operation 403 changes both the frequency spectrum of the signal and the signal probability distribution. Therefore, by performing the determination in the operation 404 and performing the loop iteration according to a result of the determination, it is possible to make both the spectrum of the notch signal and the signal probability distribution satisfy the condition.

The operations 401 to 404 will be described below.

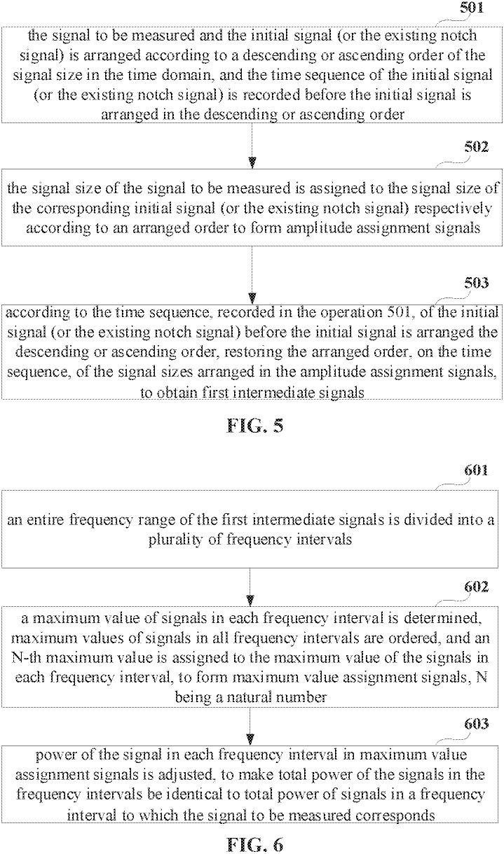

FIG. 5 is a schematic diagram of operation 401. As shown in FIG. 5, the operation 401 includes the following operations:
501, the signal to be measured and the initial signal (or the existing notch signal) is arranged according to a descending or ascending order of the signal size in the time domain, and the time sequence of the initial signal (or the existing notch signal) is recorded before the initial signal is arranged in the descending or ascending order;
502, the signal size of the signal to be measured is assigned to the signal size of the corresponding initial signal (or the existing notch signal) respectively according to an arranged order to form amplitude assignment signals; and
503, according to the time sequence, recorded in the operation 501, of the initial signal (or the existing notch signal) before the initial signal is arranged the descending or ascending order, restoring the arranged order, on the time sequence, of the signal sizes arranged in the amplitude assignment signals, to obtain first intermediate signals.

In the operation 501, the signal to be measured may be, for example, a PAM8 signal. The initial signal may be, for example, a signal having 2048 single tones with equal amplitude and random phase, wherein the 2048 single tones are equally spaced and have frequencies that are uniformly distributed throughout the spectrum of the signal to be measured. Furthermore, the signal to be measured and the initial signal may also be other types of signals. For example, the signal to be measured is a PAM signal, and the initial signal may be a single carrier Gaussian signal or a PAM signal, or a random white noise signal.

In the operations 501 to 503, when the signal to be measured and the initial signal (or the existing notch signal) are real signals, the signal size refers to the amplitude of the signal; when the signal to be measured and the initial signal (or the existing notch signal) are complex signals, the signal size refers to the modulus of the signal.

Through the operations 501 to 503, the first intermediate signal has the same signal probability distribution as the signal to be measured.

For detailed description of the operations 501 to 503, reference may be made to related art, for example, Non-Patent Document 1 (N., B.C., et al., Multisine signals for wireless system test and design. IEEE Microwave Magazine, 2008. 9(3): p. 122-138).

FIG. 6 is a schematic diagram of one implementation of operation 402. As shown in FIG. 6, the operation 402 includes the following operations:
601, an entire frequency range of the first intermediate signals is divided into a plurality of frequency intervals;
602, a maximum value of signals in each frequency interval is determined, maximum values of signals in all frequency intervals are ordered, and an N-th maximum value is assigned to the maximum value of the signals in each frequency interval, to form maximum value assignment signals, N being a natural number; and
603, power of the signal in each frequency interval in maximum value assignment signals is adjusted, to make total power of the signals in the frequency intervals be identical to total power of signals in a frequency interval to which the signal to be measured corresponds.

If the initial signal includes a plurality of single tone frequencies, each frequency interval may be made to include at least one single tone frequency in the initial signal in the operation 601. Furthermore, the present embodiment may not be limited thereto, and for example, the entire frequency range of the first intermediate signal may be divided into a plurality of frequency intervals on average or non-average.

In the operation 602, the maximum value of the signal in a frequency interval refers to the maximum value of the signal power in the frequency interval on the frequency spectrum of the first intermediate signal. The N-th maximum value may be, for example, that the maximum value of the signals in all frequency intervals (for example, if there are 100 frequency intervals and each frequency interval has one maximum value, all frequency intervals have at least 100 maximum values) are ordered in a descending order, with the maximum value ordered as the 15%-th is taken as the N-th maximum value, wherein the 15%-th is merely an example, and other values are also possible.

In the operation 603, for example, for a frequency interval with frequencies f3 to f4 in the maximum value assignment signals, the power of the signal within the frequency interval is adjusted, so that total power of the signal in the frequency interval is the same with total power of signals in a frequency interval with frequencies f3 to f4 among the signals to be measured. In the operation 603, “the same” means that the absolute value of the difference therebetween is not greater than a predetermined threshold value T2, which may be, for example, 5%, etc.

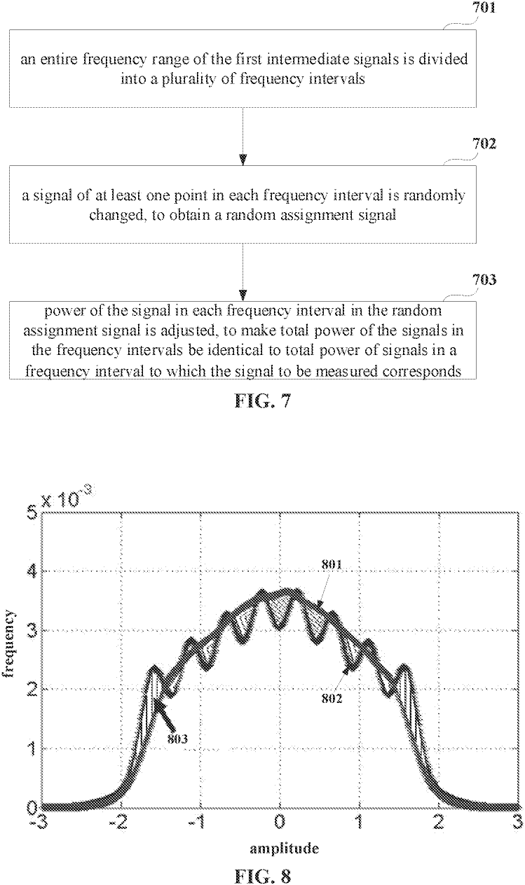

FIG. 7 is a schematic diagram of another implementation of operation 402. As shown in FIG. 7, the operation 402 includes the following operations:
701, an entire frequency range of the first intermediate signals is divided into a plurality of frequency intervals;
702, a signal of at least one point in each frequency interval is randomly changed, to obtain a random assignment signal; and
703, power of the signal in each frequency interval in the random assignment signal is adjusted, to make total power of the signals in the frequency intervals be identical to total power of signals in a frequency interval to which the signal to be measured corresponds.

The operation 701 is the same as the operation 601.

In the operation 702, randomly changing a signal of at least one point in each frequency interval refers to, for each frequency interval on the frequency spectrum of the first intermediate signal, randomly changing the power of at least one frequency point in the frequency interval, to obtain a random assignment signal. Thus, the correlation of the power of the individual frequency points in the frequency interval may be broken, so that the power of the signal and the signal probability distribution may be adjusted, respectively, so as to achieve convergence of the loop iteration, wherein the convergence of the loop iteration means that, after several times of processing of the operations 401 to 403, it is determined in the operation 404 that the current notch signal satisfies the preset condition.

In an implementation of the operation 702, for a certain frequency interval, a maximum value (such as the maximum value of the power) of a signal in the frequency interval may be determined, and a value obtained by multiplying the maximum value by a coefficient is assigned to a signal of a predetermined frequency point in the frequency interval, wherein the predetermined frequency point is, for example, the next or next few frequency points of the frequency point corresponding to the maximum value, and the coefficient is, for example, a number smaller than 1 (e.g., 0.05) or a random number.

The operation 703 is different from the operation 603 in terms of processing objects. That is, the operation 703 processes the random assignment signal and the operation 603 processes the maximum value assignment signal. The operation 703 operates in the same manner as the operation 603.

In this embodiment, the implementation of the operation 402 may not be limited to the implementation shown in FIG. 6 or FIG. 7, but may be other implementations.

In the operation 403 shown in FIG. 4, it is possible to set signals at a position of at least the notch frequency of the second intermediate signals to be of a fixed value or to be multiplied by a positive number less than 1, to generate a current notch signal. For example, the power corresponding to at least one frequency point of the second intermediate signal is assigned a fixed value such as 0. Alternatively, the power corresponding to at least one frequency point of the second intermediate signal is multiplied by a positive number smaller than 1, whereby the spectrum forms a notch at the at least one frequency point. The at least one frequency point corresponds to a notch frequency of the first signal.

In the operation 404 shown in FIG. 4, it is determined whether the current notch signal generated in the operation 403 satisfies the preset condition. The preset condition may be, for example, the difference between the signal probability distribution of the current notch signal and the signal to be measured is smaller than a predetermined value.

FIG. 8 is a schematic diagram of the signal probability distribution of the current notch signal and the signal to be measured. As shown in FIG. 8, the current notch signal and the signal to be measured are both real signals, the amplitude probability distribution of the current notch signal is represented as a curve 801, the amplitude probability distribution of the signal to be measured is represented as a curve 802, a non-overlapping area between the area covered by the curve 801 and the area covered by the curve 802 is represented as 803, and half of the area of the area 803 serves as the signal probability distribution difference (PDF difference) between the current notch signal and the signal to be measured.

As shown in FIG. 8, the horizontal axis represents the amplitude of the signal and the vertical axis represents the probability.

The PDF difference may be represented by the following formula (1):

$$P D F d i f f e r e n c e = \frac{1}{2} {\sum }_{i} \left|{P}_{1} \left(i\right) - {P}_{2} \left(i\right)\right| , {\sum }_{i} {P}_{1} \left(i\right) = 1 {\sum }_{i} {P}_{2} \left(i\right) = 1 \qquad \text{(1)}$$

In the formula (1), P₁(i) represents the probability that the amplitude of the current notch signal is i, and P₂(i) represents the probability that the amplitude of the signal to be measured is i. The PDF difference has a value between 0 and 1. When the amplitude probability distribution P₁ of the current notch signal is equal to the amplitude probability distribution P₂ of the signal to be measured, the PDF difference is 0, and when P₁ and P₂ are completely unequal, the PDF difference is 1.

In a specific embodiment, when PDF difference ≤ 0.01, it is determined in the operation 404 that the current notch signal generated in the operation 403 satisfies the preset condition, and thus, the current notch signal is taken as the first signal.

An embodiment of generating the first signal is described above by taking FIG. 4 as an example. The present application is not limited thereto, and other manners of generating the first signal, i.e., implementing the operation 201 of FIG. 2, may be adopted.

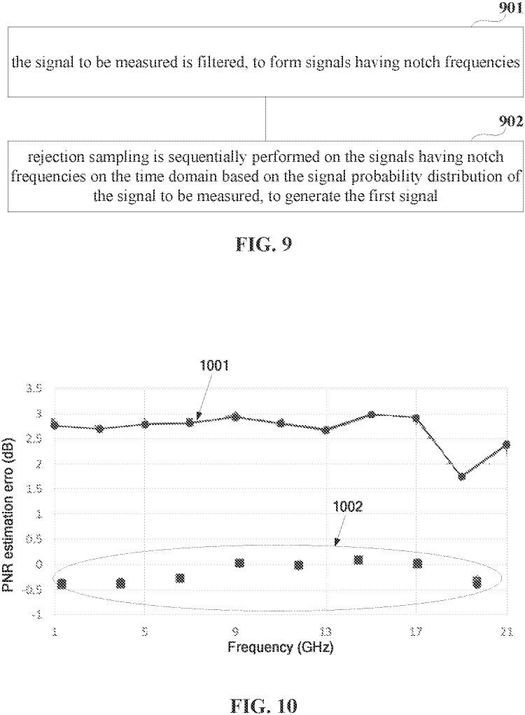

FIG. 9 is another schematic diagram of a method of generating a first signal, also for implementing operation 201 of FIG. 2.

As shown in FIG. 9, the method includes:
901, the signal to be measured is filtered, to form signals having notch frequencies; and
902, rejection sampling is sequentially performed on the signals having notch frequencies on the time domain based on the signal probability distribution of the signal to be measured, to generate the first signal.

In the operation 901, the signal to be measured may be subjected to band-stop filtering, for example, to form a signal having a notch frequency including at least one notch frequency.

In the operation 902, rejection sampling is sequentially performed on the signals having notch frequencies generated in the operation 901 on the time domain. That is, the sampling points on the signals having notch frequencies are rejected with a probability such that the signal probability distribution after the rejection sampling (amplitude probability distribution or modulus probability distribution) is equal to the signal probability distribution of the signal to be measured (amplitude probability distribution or modulus probability distribution). The signal probability distribution after the rejection sampling is equal to the signal probability distribution of the signal to be measured, which may, for example, refer to that the difference between the signal probability distribution of the signal after rejection sampling and the signal probability distribution of the signal to be measured is smaller than a predetermined value.

The first signal may also be generated by the embodiment shown in FIG. 9, thereby implementing the operation 201 of FIG. 2.

According to Embodiment 1 of the present application, a notch signal having the same signal probability distribution as the signal to be measured is generated, and based on the notch signal, nonlinear related parameters (such as nonlinear noise power) of the nonlinear device when the signal to be measured is transmitted are calculated, thus, the nonlinear related parameters may be accurately calculated for the signal to be measured having any signal probability distribution, and furthermore, the use of expensive high-frequency waveform analysis equipment may be avoided.

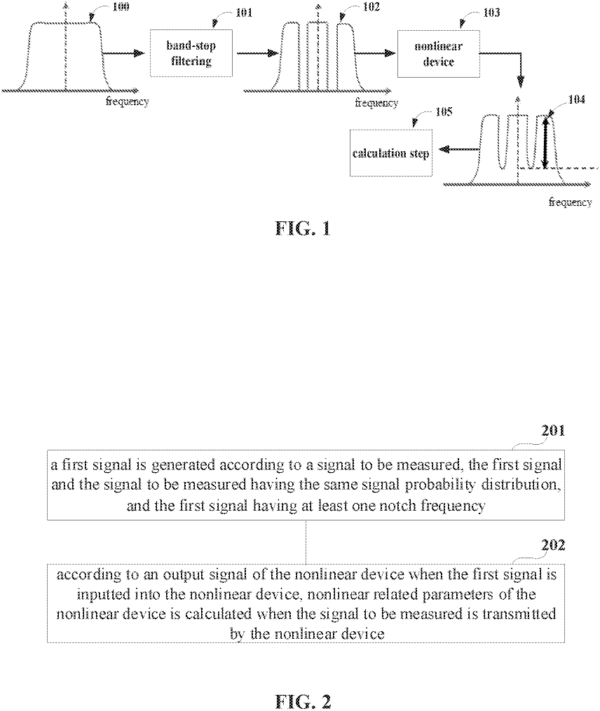

FIG. 10 is a schematic diagram of the effect of the method for measuring nonlinear related parameters of a nonlinear device according to Embodiment 1 of the present application. As shown in FIG. 10, the broken line 1001 represents the error between the PNR at different frequencies obtained using the conventional PNR test method of FIG. 1 and the actual PNR (i.e., a PNR estimation error), and the dots in the dashed circle 1002 represents the PNR estimation error obtained using the method of FIG. 2 at different frequencies. The horizontal axis represents frequency in GHz and the vertical axis represents PNR estimation error in dB.

As shown in FIG. 10, in the case of calculating PNR using the present application, the PNR estimation error is significantly smaller than the PNR estimation error obtained by the conventional PNR test method.

### Embodiment 2

Embodiment 2 further provides an apparatus for measuring nonlinear related parameters of a nonlinear device. Since the principle of the apparatus for solving the problem is similar to that of the method of Embodiment 1, the specific implementation thereof may refer to the implementation of the method of Embodiment 1, and the same contents are not repeated.

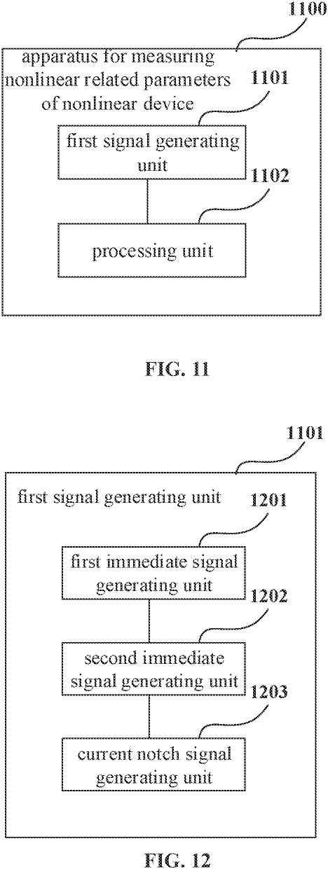

FIG. 11 is a schematic diagram of an apparatus for measuring nonlinear related parameters of a nonlinear device according to the present embodiment. As shown in FIG. 11, an apparatus 1100 for measuring nonlinear related parameters of a nonlinear device includes:
a first signal generating unit 1101 configured to generate a first signal according to a signal to be measured, the first signal and the signal to be measured having the same signal probability distribution, and the first signal having at least one notch frequency; and
a processing unit 1102 configured to, according to an output signal of the nonlinear device when the first signal is inputted into the nonlinear device, calculate nonlinear related parameters of the nonlinear device when the signal to be measured is transmitted by the nonlinear device.

In this embodiment, the implementation of the first signal generating unit 1101 and the processing unit 1102 may refer to the operation 201 and the operation 202 in Embodiment 1, which will not be described in detail herein.

In this embodiment, total power of the first signal is identical to total power of other frequency parts in the signal to be measured than the notch frequency.

FIG. 12 is a schematic diagram of one embodiment of a first signal generating unit. As shown in FIG. 12, the first signal generating unit 1101 includes:
a first intermediate signal generating unit 1201 configured to generate first intermediate signals having the same signal probability distribution as the signal to be measured based on an initial signal or an existing notch signal;
a second intermediate signal generating unit 1202 configured to adjust signals of frequency intervals in the first intermediate signals to generate second intermediate signals, power of signals in frequency intervals in the second intermediate signals being identical to power of signals in corresponding frequency intervals in the signal to be measured; and
a current notch frequency generating unit 1203 configured to set signals at a position of at least the notch frequency of the second intermediate signals to be of a fixed value or to be multiplied by a positive number less than 1, to generate a current notch signal.

In the present embodiment, when the current notch signal satisfies the preset condition, the first signal generating unit 1101 may take the current notch signal as the first signal. In addition, when the current notch signal does not satisfy the preset condition, the first signal generating unit 1101 takes the current notch signal as the existing notch signal, and performs again processing of generation of the first signal, the second signal and the current notch signal.

In an implementation, the second intermediate signal generating unit 1202 may be configured to:
divide an entire frequency range of the first intermediate signals into a plurality of frequency intervals;
determine a maximum value of signals in each frequency interval, order maximum values of signals in all frequency intervals, and assign an N-th maximum value to the maximum value of the signals in each frequency interval to form maximum value assignment signals, N being a natural number; and
adjust power of the signals in frequency intervals in the maximum value assignment signals, to make total power of the signals in the frequency intervals be identical to total power of signals in a frequency interval to which the signal to be measured corresponds, to generate the second intermediate signals.

In another embodiment, the second intermediate signal generating unit 1202 may be configured to:
divide an entire frequency range of the first intermediate signals into a plurality of frequency intervals;
randomly change a signal of at least one point in each frequency interval, to obtain a random assignment signal; and
adjust power of signals in each frequency interval, to make total power of the signals in the frequency interval be equal to total power of signals in the frequency intervals to which the signal to be measured corresponds, to generate the second intermediate signals.

For example, randomly changing a signal of at least one point in each frequency interval includes: assigning a value obtained by multiplying the maximum value of the signals in the frequency interval by a coefficient to a signal of a predetermined frequency point in the frequency interval.

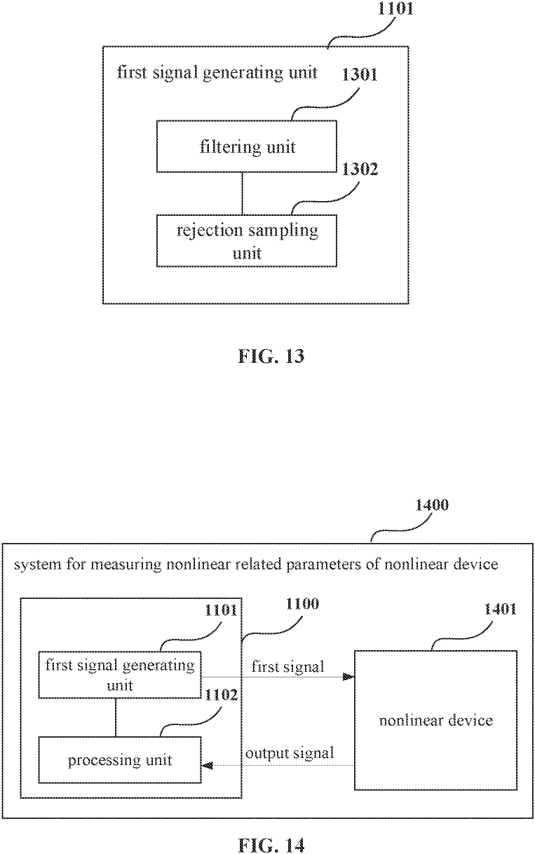

FIG. 13 is another schematic diagram of one embodiment of a first signal generating unit. As shown in FIG. 13, the first signal generating unit 1101 includes:
a filtering unit 1301 configured to filter the signal to be measured to form signals having notch frequencies; and
a sampling rejection unit 1302 configured to sequentially perform rejection sampling on the signals having notch frequencies on the time domain based on the signal probability distribution of the signal to be measured so as to generate the first signal.

In the present embodiment, detailed description of each unit may refer to the description of the corresponding operation in Embodiment 1, which will not be repeated here.

According to Embodiment 2 of the present application, a notch signal having the same signal probability distribution as the signal to be measured is generated, and based on the notch signal, nonlinear related parameters (such as nonlinear noise power) of the nonlinear device when the signal to be measured is transmitted are calculated, thus, the nonlinear related parameters may be accurately calculated for the signal to be measured having any signal probability distribution, and furthermore, the use of expensive high-frequency waveform analysis equipment may be avoided.

### Embodiment 3

Embodiments of the present application further provide a system for measuring nonlinear related parameters of a nonlinear device, including an apparatus for measuring nonlinear related parameters of a nonlinear device as described in Embodiment 2 and a nonlinear device, the contents of which are incorporated herein. The nonlinear device may be an electrical input and electrical output device, such as a radio frequency amplifier, may also be an optical input and electrical output device, such as an optical coherent receiver with a transimpedance amplifier, the input thereof being an optical signal and the output thereof being an electrical signal; however, the embodiments of the present application are not limited thereto.

FIG. 14 is a schematic diagram showing the configuration of a system for measuring nonlinear related parameters of a nonlinear device according to embodiments of the present application. As shown in FIG. 14, a system 1400 for measuring nonlinear related parameters of a nonlinear device includes: a nonlinear device 1401 and an apparatus 1100 for measuring nonlinear related parameters of a nonlinear device. The apparatus 1100 for measuring nonlinear related parameters of a nonlinear device includes a first signal generating unit 1101 and a processing unit 1102, the specific implementation of which may refer to Embodiment 2 and will not be repeated here.

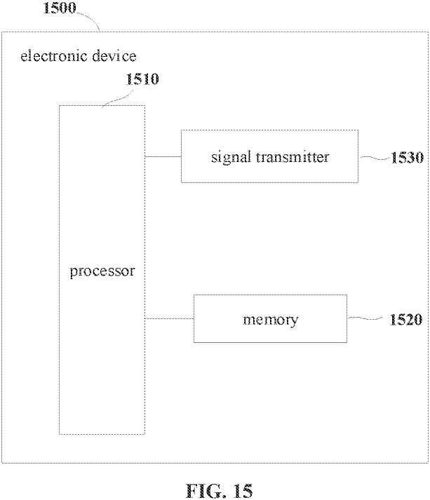

FIG. 15 is a configuration diagram of an electronic device. As shown in FIG. 15, an electronic device 1500 includes a processor (such as a digital signal processor (DSP)) 1510 and a memory 1520; the memory 1520 is coupled to the processor 1510. The memory 1520 may store various data; a program for information processing is also stored and the program is executed under the control of the processor 1510. In addition, the electronic device 1500 also includes a signal transmitter 1530. The electronic device 1500 may implement the function of the apparatus 1100 for measuring nonlinear related parameters of the nonlinear device.

In an implementation, the function of the apparatus 1100 for measuring nonlinear related parameters of the nonlinear device may be integrated into the processor 1510. Wherein, the processor 1510 may be configured to implement the method for measuring nonlinear related parameters of a nonlinear device as described in Embodiment 1.

In another implementation, the apparatus 1100 for measuring nonlinear related parameters of the nonlinear device may be configured separately from the processor 1510. For example, the apparatus 1100 for measuring nonlinear related parameters of the nonlinear device may be configured as a chip connected to the processor 1510, the function of the apparatus 1100 for measuring nonlinear related parameters of the nonlinear device being performed by the control of the processor 1510.

It should be noted that the electronic device 1500 is not necessarily required to include all of the components shown in FIG. 15; in addition, the electronic device 1500 may further include components not shown in FIG. 15, with reference to the related art.

Through the embodiments of the present application, a notch signal having the same signal probability distribution as the signal to be measured is generated, and based on the notch signal, nonlinear related parameters (such as nonlinear noise power) of the nonlinear device when the signal to be measured is transmitted are calculated, thus, the nonlinear related parameters may be accurately calculated for the signal to be measured having any signal probability distribution format, and furthermore, the use of expensive high-frequency waveform analysis equipment may be avoided.

Embodiments of the present application also provide a computer-readable program, wherein when the program is executed in an apparatus for measuring nonlinear related parameters of the nonlinear device, the program causes a computer to execute, in the apparatus for measuring nonlinear related parameters of the nonlinear device, the method for measuring nonlinear related parameters of a nonlinear device as described above in Embodiment 1.

Embodiments of the present application further provide a storage medium in which a computer-readable program is stored, wherein the computer-readable program causes the computer to execute, in the apparatus for measuring nonlinear related parameters of the nonlinear device, the method for measuring nonlinear related parameters of a nonlinear device as described above in Embodiment 1.

The method of measuring filtering characteristics in an apparatus for measuring filtering characteristics described in connection with the embodiments in the present application may be embodied directly in hardware, a software module executed by a processor, or a combination of both. For example, one or more of the functional block diagrams and/or one or more combinations of the functional block diagrams shown in the drawings may correspond to each software module or each hardware module of a computer program flow. These software modules may correspond to the respective steps shown in the drawings. The hardware modules may be implemented, for example, by solidifying the software modules using a field programmable gate array (FPGA).

A software module may be located in an RAM memory, a flash memory, an ROM memory, an EPROM memory, an EEPROM memory, a register, a hard disk, a removable disk, a CD-ROM, or any other form of storage medium known in the art. A storage medium may be coupled to the processor to enable the processor to read information from and write information to the storage medium, or the storage medium may be an integral part of the processor. The processor and the storage medium may reside in an ASIC. The software module may be stored in a memory of the apparatus for measuring the filtering characteristic or in a memory card insertable into the apparatus for measuring the filtering characteristic.

One or more of the functional block diagrams and/or one or more combinations of the functional block diagrams shown in the drawings may be implemented as a general purpose processor, a digital signal processor (DSP), an application specific integrated circuit (ASIC), a field programmable gate array (FPGA) or other programmable logic devices, a discrete gate or a transistor logic device, a discrete hardware component, or any suitable combination thereof designed to perform the functions described in the present application. One or more of the functional block diagrams and/or one or more combinations of the functional block diagrams may also be implemented as combination of computing devices, e.g., combination of a DSP and a microprocessor, a plurality of microprocessors, one or more microprocessors in communication with the DSP, or any other such configuration.

The present application is described in combination with specific embodiments hereinabove, but a person skilled in the art should know clearly that the description is exemplary, but not limitation to the protection scope of the present application. A person skilled in the art may make various variations and modifications to the present application according to spirit and principle of the application, and these variations and modifications should also be within the scope of the present application.

Regarding the embodiments including the above multiple embodiments, the following supplements are also disclosed:

In an example, an electronic device may include a processor and a memory, the memory storing a computer-readable program, when executing the computer-readable program, the processor implementing a method for measuring nonlinear related parameters of a nonlinear device, the method including:
generating a first signal according to a signal to be measured, the first signal and the signal to be measured having the same signal probability distribution, and the first signal having at least one notch frequency; and
according to an output signal of the nonlinear device when the first signal is inputted into the nonlinear device, calculating nonlinear related parameters of the nonlinear device when the signal to be measured is transmitted by the nonlinear device.

In an example, according to the electronic device of the supplement 1, total power of the first signal is identical to total power of other frequency parts in the signal to be measured than the notch frequency.

In an example, according to the electronic device of the supplement 1, a method for generating the first signals includes:
generating first intermediate signals having the same signal probability distribution as the signal to be measured based on an initial signal or an existing notch signal;
adjusting signals of frequency intervals in the first intermediate signals to generate second intermediate signals, power of signals in frequency intervals in the second intermediate signals being identical to power of signals in a frequency interval to which the signal to be measured corresponds; and
setting signals at a position of at least the notch frequency of the second intermediate signals to be of a fixed value or to be multiplied by a positive number less than 1, to generate a current notch signal,
and when the current notch signal satisfies a preset condition, the current notch signal is taken as the first signal.

In an example, according to the electronic device of the supplement 3, wherein,
when the current notch signal does not satisfy the preset condition,
the current notch signal is taken as the existing notch signal, and generation of the first signal, the second signal and the current notch signal is performed again.

In an example, according to the electronic device of the supplement 3, a method for generating the second intermediate signals includes:
dividing an entire frequency range of the first intermediate signals into a plurality of frequency intervals;
determining a maximum value of signals in each frequency interval, ordering maximum values of signals in all frequency intervals, and assigning an N-th maximum value to the maximum value of the signals in each frequency interval to form maximum value assignment signals, N being a natural number; and
adjusting power of the signals in frequency intervals in the maximum value assignment signals, to make total power of the signals in the frequency intervals be identical to total power of signals in a frequency interval to which the signal to be measured corresponds, to generate the second intermediate signals.

In an example, according to the electronic device of the supplement 3, a method for generating the second intermediate signals includes:
dividing an entire frequency range of the first intermediate signals into a plurality of frequency intervals;
randomly changing a signal of at least one point in each frequency interval, to obtain a random assignment signal; and
adjusting power of signals in each frequency interval, to make total power of the signals in the frequency interval is equal to total power of signals in frequency intervals to which the signal to be measured corresponds, to generate the second intermediate signals.

In an example, according to the electronic device of the supplement 6, wherein that randomly change a signal of at least one point in each frequency interval includes:

assigning a value obtained by multiplying the maximum value of the signals in the frequency interval by a coefficient to a signal of a predetermined frequency point in the frequency interval.

In an example, according to the electronic device of the supplement 1, wherein, a method for generating the first signals includes:
filtering the signal to be measured to form signals having notch frequencies; and
sequentially performing rejection sampling on the signals having notch frequencies on the time domain based on the signal probability distribution of the signal to be measured, to generate the first signal.

In an example, a storage medium storing a computer-readable program for causing a computer to implement a method for measuring nonlinear related parameters of a nonlinear device is provided, the method including:
generating a first signal according to a signal to be measured, the first signal and the signal to be measured having the same signal probability distribution, and the first signal having at least one notch frequency; and
according to an output signal of the nonlinear device when the first signal is inputted into the nonlinear device, calculating nonlinear related parameters of the nonlinear device when the signal to be measured is transmitted by the nonlinear device.

In an example, according to the storage medium of the supplement 9,

total power of the first signal is identical to total power of other frequency parts in the signal to be measured than the notch frequency.

In an example, according to the storage medium of the supplement 9, a method for generating the first signals includes:
generating first intermediate signals having the same signal probability distribution as the signal to be measured based on an initial signal or an existing notch signal;
adjusting signals of frequency intervals in the first intermediate signals to generate second intermediate signals, power of signals in frequency intervals in the second intermediate signals being identical to power of signals in frequency intervals to which the signal to be measured corresponds; and
setting signals at a position of at least the notch frequency of the second intermediate signals to be of a fixed value or to be multiplied by a positive number less than 1, to generate a current notch signal,
and when the current notch signal satisfies a preset condition, the current notch signal is taken as the first signal.

In an example, according to the storage medium according to the supplement 11,
when the current notch signal does not satisfy the preset condition,
the current notch signal is taken as the existing notch signal, and generation of the first signal, the second signal and the current notch signal is performed again.

In an example, according to the storage medium of the supplement 11, the method for generating the second intermediate signals includes:
dividing an entire frequency range of the first intermediate signals into a plurality of frequency intervals;
determining a maximum value of signals in each frequency interval, ordering maximum values of signals in all frequency intervals, and assigning an N-th maximum value to the maximum value of the signals in each frequency interval to form maximum value assignment signals, N being a natural number; and
adjusting power of the signals in frequency intervals in the maximum value assignment signals, to make total power of the signals in the frequency intervals be identical to total power of signals in a frequency interval to which the signal to be measured corresponds, to generate the second intermediate signals.

In an example, according to the storage medium according to the supplement 11, the method for generating the second intermediate signals includes:
dividing an entire frequency range of the first intermediate signals into a plurality of frequency intervals;
randomly changing a signal of at least one point in each frequency interval, to obtain a random assignment signal; and
adjusting power of signals in each frequency interval so that total power of the signals in the frequency interval is equal to total power of signals in frequency intervals to which the signal to be measured corresponds, to generate the second intermediate signals.

In an example, according to the storage medium of the supplement 14, randomly changing a signal of at least one point in each frequency interval includes:

assigning a value obtained by multiplying the maximum value of the signals in the frequency interval by a coefficient to a signal of a predetermined frequency point in the frequency interval.

In an example, according to the storage medium of the supplement 9, the method for generating the first signal includes:
filtering the signal to be measured to form signals having notch frequencies; and
sequentially performing rejection sampling on the signals having notch frequencies on the time domain based on the signal probability distribution of the signal to be measured, to generate the first signal.

What is claimed is:

1. An apparatus to measure nonlinear related parameters of a nonlinear device, comprising:
a memory; and
a processor coupled to the memory to control execution of a process to:
generate a first signal according to a signal to be measured, the first signal and the signal to be measured having a signal probability distribution that is same, and the first signal having at least one notch frequency; and
calculate, according to an output signal of the nonlinear device when the first signal is input into the nonlinear device, nonlinear related parameters of the nonlinear device when the signal to be measured is transmitted by the nonlinear device.

2. The apparatus according to claim 1, wherein,
total power of the first signal is identical to total power of other frequency parts in the signal to be measured than the at least one notch frequency.

3. The apparatus according to claim 1, wherein to generate the first signal, the process comprises:
generating first intermediate signals having signal probability distribution that is same as the signal to be measured based on an initial signal or an existing notch signal;
adjusting signals of frequency intervals in the first intermediate signals to generate second intermediate signals, power of signals in frequency intervals in the second intermediate signals being identical to power of signals in corresponding frequency intervals in the signal to be measured; and
set signals at a position of at least a notch frequency of the second intermediate signals to be of a fixed value or to be multiplied by a positive number less than 1, to generate a current notch signal, and
when the current notch signal satisfies a preset condition, the current notch signal is taken as the first signal.

4. The apparatus according to claim 3, wherein,
when the current notch signal does not satisfy the preset condition,
the current notch signal is taken as the existing notch signal, and to generate the first signal, the process performs generation of the first signal, a second signal and the current notch signal.

5. The apparatus according to claim 3, wherein the adjusting signals of frequency intervals in the first intermediate signals to generate second intermediate signals comprises:
dividing an entire frequency range of the first intermediate signals into a plurality of frequency intervals;
determining a maximum value of signals in each frequency interval, order maximum values of signals in all frequency intervals, and assign an N-th maximum value to the maximum value of the signals in each frequency interval to form maximum value assignment signals, N being a natural number; and
adjusting power of the signals in frequency intervals in the maximum value assignment signals, to make total power of the signals in the frequency intervals be identical to total power of signals in a frequency interval to which the signal to be measured corresponds, to generate the second intermediate signals.

6. The apparatus according to claim 3, wherein the adjusting signals of frequency intervals in the first intermediate signals to generate second intermediate signals comprises:
divide an entire frequency range of the first intermediate signals into a plurality of frequency intervals;
randomly change a signal of at least one point in each frequency interval, to obtain a random assignment signal; and
adjust power of signals in each frequency interval, to make total power of the signals in the frequency interval be equal to total power of signals in frequency intervals to which the signal to be measured corresponds, to generate the second intermediate signals.

7. The apparatus according to claim 6, wherein the randomly change a signal of at least one point in each frequency interval comprises:
assigning a value obtained by multiplying a maximum value of the signals in the frequency interval by a coefficient to a signal of a predetermined frequency point in the frequency interval.

8. The apparatus according to claim 1, wherein to generate the first signal, the process comprises:
filtering the signal to be measured to form signals having notch frequencies; and
sequentially perform rejection sampling on the signals having notch frequencies on a time domain based on the signal probability distribution of the signal to be measured, to generate the first signal.

9. A system to measure nonlinear related parameters of a nonlinear device, comprising a nonlinear device and an apparatus to measure nonlinear related parameters of the nonlinear device as claimed in claim 1.

10. A method to measure nonlinear related parameters of a nonlinear device, comprising:
generating a first signal according to a signal to be measured, the first signal and the signal to be measured having a signal probability distribution that is same, and the first signal having at least one notch frequency; and
calculating, according to an output signal of the nonlinear device when the first signal is input into the nonlinear device, nonlinear related parameters of the nonlinear device when the signal to be measured is transmitted by the nonlinear device.

11. The method according to claim 10, wherein,
total power of the first signal is identical to total power of other frequency parts in the signal to be measured than the at least one notch frequency.

12. The method according to claim 10, wherein the generating the first signals comprises:
generating first intermediate signals having a signal probability distribution that is same as the signal to be measured based on an initial signal or an existing notch signal;
adjusting signals of frequency intervals in the first intermediate signals to generate second intermediate signals, power of signals in frequency intervals in the second intermediate signals being identical to power of signals in corresponding frequency intervals in the signal to be measured; and
setting signals at a position of at least a notch frequency of the second intermediate signals to be of a fixed value or to be multiplied by a positive number less than 1, to generate a current notch signal, and
when the current notch signal satisfies a preset condition, the current notch signal is taken as the first signal.

13. The method according to claim 12, wherein,
when the current notch signal does not satisfy the preset condition,
the current notch signal is taken as the existing notch signal, and generation of the first signal, a second signal and the current notch signal is performed.

14. The method according to claim 12, wherein a method for generating the second intermediate signals comprises:
dividing an entire frequency range of the first intermediate signals into a plurality of frequency intervals;
determining a maximum value of signals in each frequency interval, ordering maximum values of signals in all frequency intervals, and assigning an N-th maximum value to the maximum value of the signals in each frequency interval to form maximum value assignment signals, N being a natural number; and
adjusting power of the signals in frequency intervals in the maximum value assignment signals, to make total power of the signals in the frequency intervals be identical to total power of signals in a frequency interval to which the signal to be measured corresponds, to generate the second intermediate signals.

15. The method according to claim 12, wherein the generating of the second intermediate signals comprises:
dividing an entire frequency range of the first intermediate signals into a plurality of frequency intervals;
randomly changing a signal of at least one point in each frequency interval, to obtain a random assignment signal; and
adjusting power of signals in each frequency interval, to make total power of the signals in the frequency interval be equal to total power of signals in frequency intervals to which the signal to be measured corresponds, to generate the second intermediate signals.

16. The method according to claim 15, wherein the randomly changing a signal of at least one point in each frequency interval comprises:
assigning a value obtained by multiplying a maximum value of the signals in the frequency interval by a coefficient to a signal of a predetermined frequency point in the frequency interval.

17. The method according to claim 10, wherein a method for generating the first signals comprises:
filtering the signal to be measured to form signals having notch frequencies; and
sequentially performing rejection sampling on the signals having notch frequencies on a time domain based on the signal probability distribution of the signal to be measured, to generate the first signal.
